(19) United States
(12) Patent Application Publication
(10) Pub. No.: US 2002/0190288 A1
(43) Pub. Date: Dec. 19, 2002

(54) CMOS type image sensor

(75) Inventors: Youn-Jung Lee, Sungnam-shi (KR); Gue-Hyung Kwon, Ansan-shi (KR); Jung-Chak Ahn, Suwon (KR)

Correspondence Address: Steven M. Mills, MILLS & ONELLO LLP, Suite 605, Eleven Beacon Street, Boston, MA, 02108, US

(73) Assignee: Samsung Electronics Co., Ltd.

(21) Appl. No.: 10/174,324

(22) Filed: Jun. 18, 2002

(30) Foreign Application Priority Data
Jun. 19, 2001 (KR) 2001-34737

(51) Int. Cl. H01L 31/062; H01L 31/113

(52) U.S. Cl. 257/292; 257/290; 257/291

(57) ABSTRACT

A CMOS image sensor has at least one pixel at a region for sensing an image. Each pixel has a semiconductor substrate doped by a first conductivity type, a photodiode region formed of a second conductivity type shallowly at the surface of the semiconductor substrate and a reset transistor. Source/drain regions of the reset transistor are doped by the second conductivity type, and especially, the source region is doped by the second conductivity type impurity. One part of the photodiode region is covered by a pinning layer doped by the first conductivity type and becomes a fixed region. The other part of the photodiode region is an open region, adjacent to the gate electrode of the reset transistor, and partially overlapped with the source region of the reset transistor, but not covered by the pinning layer.

### RELATED APPLICATION

This application relies for priority upon Korean Patent Application No. 2001-34737, filed on Jun. 19, 2001, the contents of which are herein incorporated by reference in their entirety.

### FIELD OF THE INVENTION

The present invention relates to a solid image sensor, and more particularly, to a pixel structure of a CMOS type image sensor (CIS).

### BACKGROUND OF THE INVENTION

Solid image sensors include CCD type image sensors using charge coupled devices (CCD) and complementary metal oxide semiconductor (CMOS) type image sensors. CMOS transistor type image sensors include a 4-transistor type using four transistors per a pixel and a 3-transistor type using three transistors per a pixel. In U.S. Pat. Nos. 6,051,447 and 5,903,021, assigned to the Eastman Kodak Co., a structure and a method of forming the CMOS type image sensor of the 3-transistor type is disclosed.

FIG. 1 contains a schematic circuit diagram showing the structure of a unit pixel in a conventional CMOS type image sensor of a 3-transistor type. FIG. 2 illustrates a plan view showing an example of a plan structure of a unit pixel. FIG. 3 illustrates a cross-sectional view showing a partially filled pinned photodiode (PFPP) taken along the I-I′ line of FIG. 2. The view of FIG. 2 illustrates the cross-sectional structure of a substrate including a photodiode and a reset transistor.

Referring to FIGS. 1 through 3, an individual sensing pixel used in a sensing screen includes one photodiode 11 and three transistors 13, 15 and 17. An N-type impurity region 110 of the photodiode 11, includes a first portion 170 covered by a P-type pinning layer 120 and a source region 130 doped by a highly concentrated NMOS type reset transistor 13. The portion 170 and the source region 130 are formed in the region 110, so that the entire N-type impurity region 110 of the photodiode 11 acts as a source region of the reset transistor 13. Photo electrons generated from the photodiode 11 are accumulated in the source region 130 of the reset transistor 13. In order to measure the amount of photo electrons accumulated, a terminal of a residual circuit is connected with the source region 130 of the reset transistor 13 in the N-type impurity region 180 not covered by the P-type pining layer 120. A clock signal is periodically applied at a gate electrode 150 of the reset transistor 13 spaced from a substrate 100 by a gate insulation layer 160, to output the accumulated photo electrons to a drain region 140 of the reset transistor 13. The source region 130 connected by the residual circuit terminal is formed of a highly concentrated N-type impurity region formed differently from other regions of the photodiode 11. Thus, the photo electrons are first accumulated in the source region 130.

The residual circuit connected with the photodiode 11 has the same structure as a source follower connected with a horizontal transfer stage of the CCD type image sensor. Through the terminal, the source region 130 is connected with a gate electrode of a read out transistor 15 of a source follower circuit. The drain of the read out transistor 15 is connected to a constant voltage V_{DD}, and the source is connected to the drain of a row selection transistor 17 or an address transistor. A source potential of the reset transistor 13 varies according to the amount of accumulated photo electrons, and the source potential is applied at the gate of the read out transistor 15. The gate electrode of the row selection transistor 17 is connected with a gate line 19 crossing the entire screen composed of pixels from the left to the right, and the source of the row selection transistor 17 is connected to a constant current power supply 21 and an output terminal Vout. When a clock signal is applied through a gate line 19 at the gate electrode of the row selection transistor 17, the voltage applied at the source of the read out transistor 15 is outputted as an output voltage Vout of a pixel.

According to the structure, in comparison with the CMOS type image sensor of the 4-transistor type having the former transfer gate and a floating diffusion, it is possible to increase the fill factor, which is a ratio of the area of the photodiode to the area of the pixel. If the floated region of the photodiode part is reduced, the parasitic capacitance is reduced, and thus the pixel may have a high sensitivity with respect to external light. In the former step, an image lag resulting from remnant photo electrons may be reduced. Also, in case of using an over flow of the photo electrons by controlling doping concentration of the reset transistor channel, it is possible to prevent a blooming phenomenon generated in a bright region, where a pixel receiving light which exceeds a usual level affects neighboring pixels.

According to a conventional structure, the source region 130 of the reset transistor, which is a high-concentration N-type doping region connected with a residual circuit through a terminal in order to measure the brightness of the corresponding pixel, is defined in the N-type impurity region 110 of the photodiode portion of the device. In this configuration, if the source region 130 is inscribed in the N-type impurity region 110, as shown in FIG. 3, it does not result in a problem. But, if an ion-implantation mask is moved to the left somewhat by misalignment while implanting highly concentrated N-type ions, a region 190 of low-concentration N-type impurity region 110 is present between a channel region under the gate electrode 150 of the reset transistor and the source region 130′ of the high-concentration N-type doping region. The region 190 acts as a potential barrier when flowing out the photo electrons to a drain region 140 of the reset transistor 13. FIG. 5 contains a graph showing potential distribution taken along a II-II′ line in the doping region like FIG. 4.

In case that the potential barrier 190′ is present as illustrated in FIG. 5, even in the ‘on’ state when the channel is opened by applying a clock signal at the gate electrode of a reset transistor, the flow-out of the photo electrons is not completely carried. Thus, the reset function does not operate properly, image lag is introduced, and the transferred image is distorted.

### SUMMARY OF THE INVENTION

It is an object of the present invention to provide a CMOS type image sensor (CIS) in which a reset function operates normally to measure the brightness of the corresponding image region exactly in a solid image sensor at a specific time.

It is another object of the present invention to provide a CMOS type image sensor in which influence of the photo electrons accumulated in a former step or influence of an image of the former step may be sufficiently eliminated.

It is still another object of the present invention to provide a CMOS type image sensor capable of increasing process margin.

The present invention is directed to a CMOS image sensor. The CMOS image sensor has at least a pixel at a region sensing an image. Each pixel has a semiconductor substrate doped by a first conductivity type impurity, a photodiode region doped by a relatively low-concentration second conductivity type impurity at the surface of the semiconductor substrate at a pixel portion of the substrate, and a MOS reset transistor. The photodiode region is divided into an open region and a fixed region having a pinning layer whose top portion is doped by the first conductivity type impurity. The MOS transistor has a source region that is partially overlapped with the photodiode region at the open region and doped by a relatively high-concentration second conductivity type impurity.

Source/drain regions of the reset transistor are doped with impurities of the second conductivity type, and, in particular. the source region is doped by the second conductivity type impurity of a high-concentration. One part of the photodiode region becomes a fixed region covered by the pinning layer whose top part is doped by the first conductivity type. An open region, which is another part of the photodiode region and adjacent to the gate electrode of the reset transistor, is not covered by the pinning layer, and is partially overlapped with the source region of the reset transistor. That is, the source region of the reset transistor is partially overlapped by a region which is not covered by the pinning layer of the photodiode region.

In the present invention, the source region may be partially overlapped with the gate electrode of the reset transistor, and the open region of the photodiode region may reach to the sidewall of the gate electrode. Alternatively, the source region may reach to the sidewall of the gate electrode of the reset transistor and the open region of the photodiode region may be spaced from the sidewall of the gate electrode by a certain distance. The certain distance is preferably a half of the width of the source region for increasing a process margin in a process of forming an image sensor.

The channel region of the reset transistor may be doped by the same conductivity type impurity as the photodiode region but with a lower concentration than the photodiode region. In this case, in the state that a voltage is not applied at the gate electrode of the reset transistor, the potential of the channel region is lower than that of the photodiode region and higher than zero potential, so that over flow is generated to prevent a blooming phenomenon.

However, in the present invention, the channel of the reset transistor may be formed of a general surface channel or a buried channel.

Other structures except for the specific structure of the present invention, such as a source follower circuit composed of a read out transistor and a row selection transistor, may be formed similarly with a conventional CMOS type image sensor of the 3-transistor type.

### BRIEF DESCRIPTION OF THE DRAWINGS

The foregoing and other objects, features and advantages of the invention will be apparent from the more particular description of a preferred embodiment of the invention, as illustrated in the accompanying drawings in which like reference characters refer to the same parts throughout the different views. The drawings are not necessarily to scale, emphasis instead being placed upon illustrating the principles of the invention.

FIG. 1 contains a schematic circuit diagram showing a structure of a unit pixel of a conventional CMOS type image sensor of a 3-transistor type.

FIG. 2 contains a plan view showing a structure of a unit pixel.

FIG. 3 contains a cross-sectional view illustrating a cross-sectional structure of a substrate including a photodiode and a reset transistor, taken along the I-I′ line of FIG. 2.

FIG. 4 contains a cross-sectional view showing distorted structure of a substrate including a photodiode and a reset transistor, resulting from misalignment in implanting ions.

FIG. 5 contains a graph showing potential distribution taken along the II-II′ line in a doping region such as that shown in FIG. 4.

FIG. 6 contains a plan view of a substrate of a pixel according to an embodiment of the present invention.

FIG. 7 contains a cross-sectional view showing a doping state of a substrate of a pixel taken along line I-I′ of FIG. 1.

FIG. 8 contains a graph showing potential of each doping region measured along a dotted line III-III′ at the cross-sectional view of FIG. 7.

### DETAILED DESCRIPTION OF THE PREFERRED EMBODIMENT

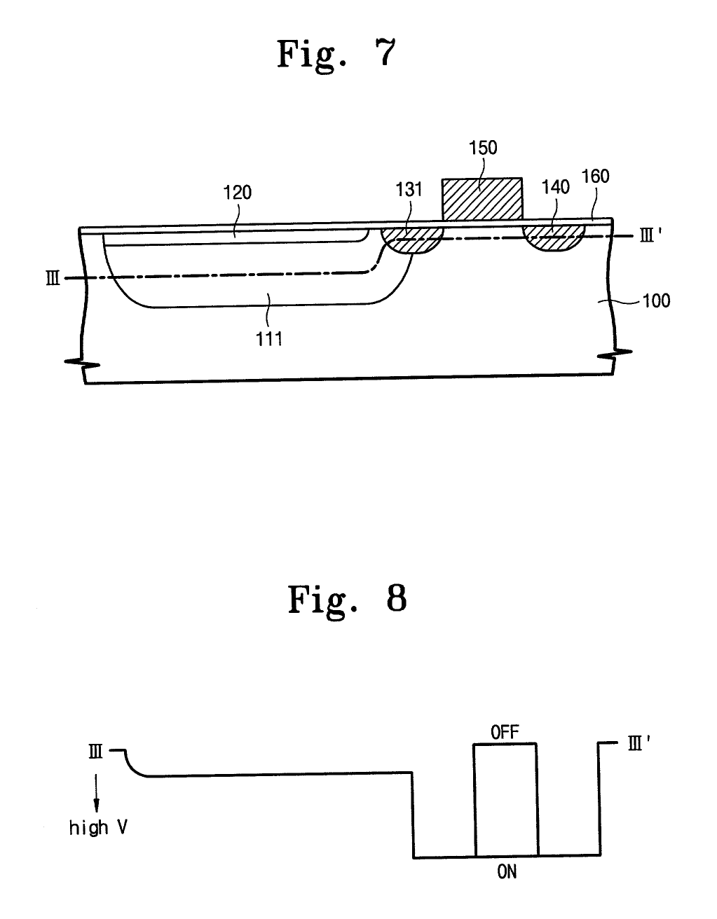

Referring to FIGS. 6 and 7, an isolation layer is formed to separate an image region into pixels. Each pixel is composed of a semiconductor substrate 100 doped by low-concentration P-type impurities. A gate insulation layer 160 is formed at the entire surface of the substrate 100. An N-type impurity region 111 is formed by doping at a partial surface of an active region composing each pixel to compose a photodiode together with the P-type impurity-doped region of the substrate 100. In FIG. 7, a gate electrode 150 of a reset transistor, spaced from the substrate by the gate insulation layer 160, is formed at the right side, i.e., outside of the photodiode region. Source/drain regions 131 and 140 doped by high-concentration N-type impurities are formed at both sides of the gate electrode 150 to a predetermined depth. The source region 131 of the reset transistor is partially overlapped with the N-type impurity region 111 composing a photodiode region. A pinning layer 120 doped by P-type impurities is shallowly formed at the photodiode region and apart from the reset transistor.

Referring to FIG. 8, if the substrate is grounded, the area where the photodiode region is connected with the substrate has the zero potential. Since most of the photodiode region is homogeneously doped by low-concentration N-type impurities, a potential of a certain value that is somewhat higher than the zero potential is formed. The potential is further increased at the source region of the reset transistor doped by the high-concentration N-type impurity. The channel under the gate electrode of the reset transistor is doped by the P-type impurities and composes the substrate, so that the potential has zero state, when the clock signal is not applied at the gate electrode. That is, the channel keeps a lower potential than the low-concentration N-type impurity-doping region of the photodiode region. The potential of the channel part can be controlled by concentration of impurities doped at the channel. For example, a few N-type impurities are implanted to keep a higher potential than the zero potential. If the channel has a higher value than the zero potential, over flow resulting from the accumulated photo electrons exceeding the channel potential may be generated to prevent a blooming phenomenon. The drain region of the reset transistor is doped by the high-concentration N-type impurities to have a high potential together with the source region.

If a voltage is not applied at a gate electrode, the gate acts as a potential barrier. The photo electrons, generated at the boundary part of the photodiode region by receiving external light, are accumulated at the photodiode region, especially at a high-potential source region of the reset transistor overlapped with the photodiode region, to decrease the potential. If the potential is below a certain value, the photo electrons are accumulated at the entire photodiode region which is a low-concentration N-type impurity doping region. Thus, as illustrated in FIG. 8, even in the case in which light having a certain brightness is directed at the pixel over time, the rate at which the potential is reduced according to the accumulated photo electrons may change at a certain potential level.

If a reset voltage, which is a kind of the clock signal, is applied at a gate of the reset transistor, the potential of the channel is increased to have a high value like the neighboring high-concentration N-type impurity doping region. Thus, the photo electrons accumulated at the source region and the photodiode region are discharged through the drain region of the reset transistor.

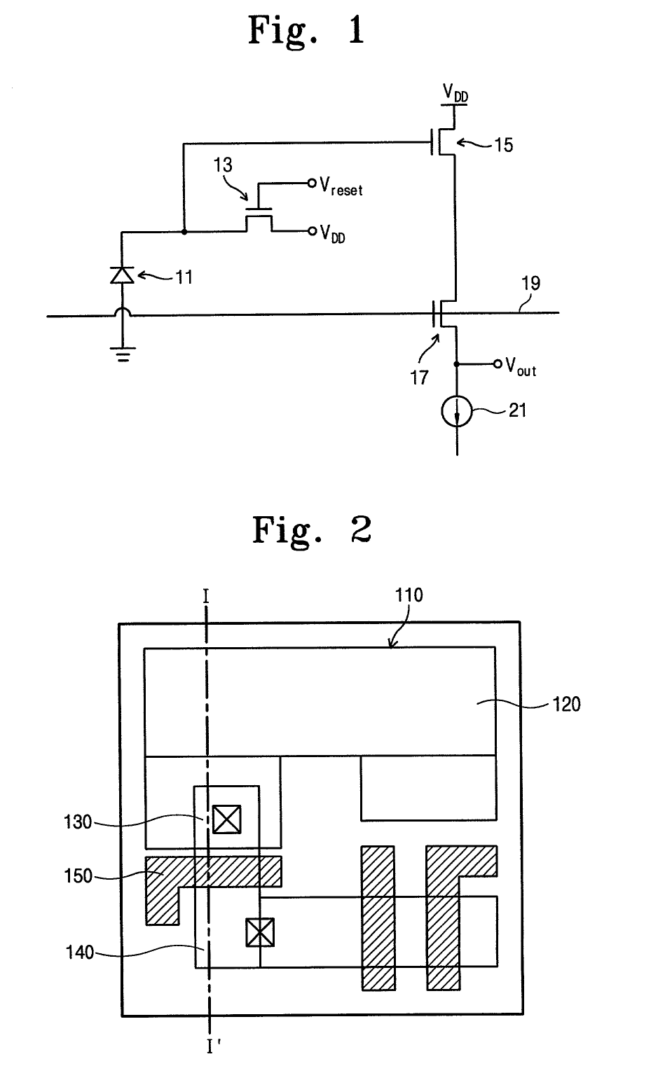

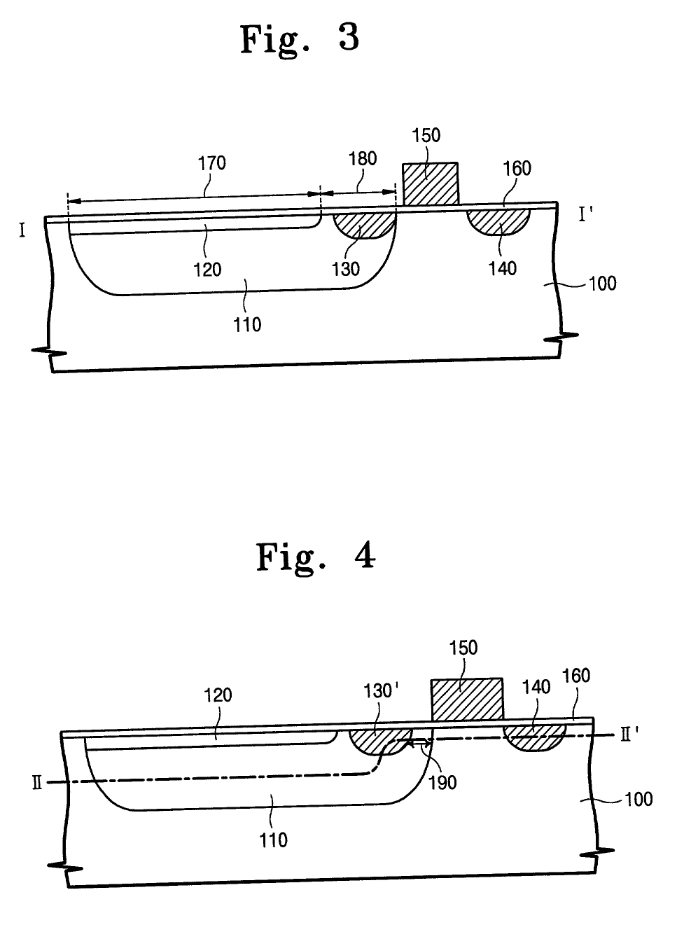

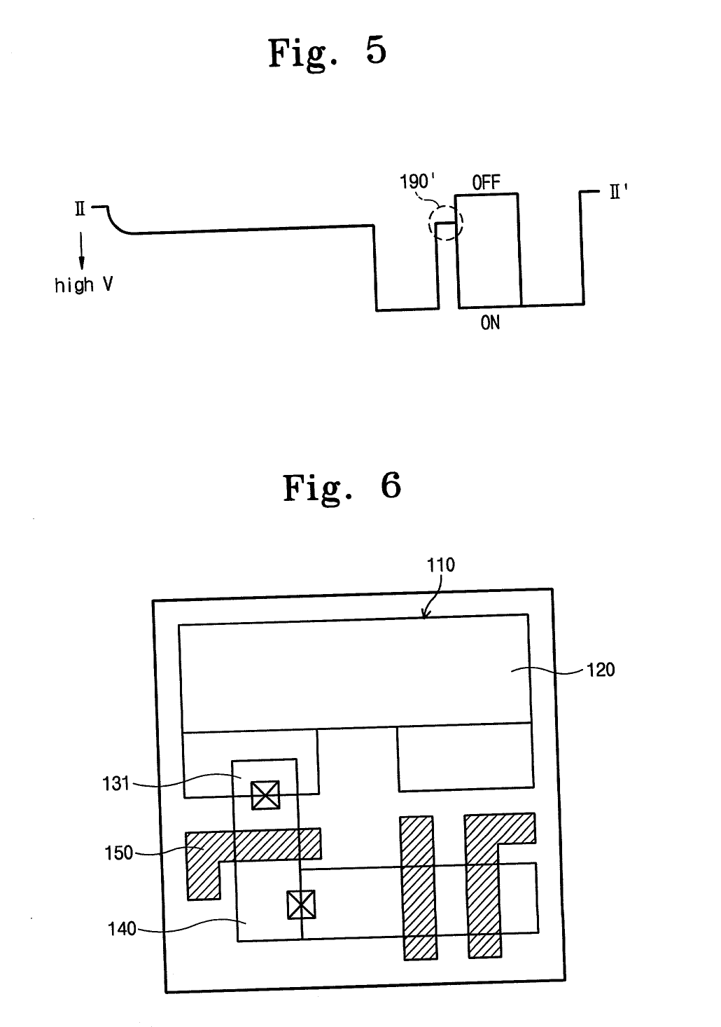

If the reset voltage is removed from the gate electrode, the potential barrier of the channel is restored as a low potential. Thus, according to the external light, photo electrons are sequentially accumulated at the source region and the photodiode region, again. The potential according to the amount of photo electrons accumulated at the source region acts as a gate voltage of the read out transistor of the source follower circuit like FIG. 1. After a certain time has passed since the reset voltage was removed, a voltage is applied according to a clock signal at a gate of a row selection transistor. Thus, another voltage applied at a region which is a source of the read out transistor and also a drain of the row selection transistor is directly applied at a source of the row selection transistor as the channel of the row selection transistor transitions to the ‘on’ state. The other voltage applied at a source of the read out transistor has a correlation with the potential of the source of the reset transistor changed according to the photo electrons that have accumulated at the source of the reset transistor and the photodiode region for a certain time. Consequently, the potential dependent on the amount of the photo electrons accumulated at the source of the reset transistor is outputted as an output signal of the pixel and transferred to a display apparatus for restoring an image.

According to the present invention, a low-concentration doping region is not interposed between a high-concentration doping region and a channel region of the reset transistor, at a photodiode region. Thus, even under photomask misalignment of an ion-injection mask in a process of forming a CMOS type image sensor, a reset function operates normally, and photo electrons accumulated in a former step may not influence a process condition in the next step.

While this invention has been particularly shown and described with reference to preferred embodiments thereof, it will be understood by those skilled in the art that various changes in form and details may be made therein without departing from the spirit and scope of the invention as defined by the appended claims.

What is claimed is:

1. A CMOS type image sensor comprising at least one pixel at a region sensing an image, wherein the pixel comprises:
a semiconductor substrate doped by a first conductivity type impurity;
a photodiode region doped by a relatively low-concentration second conductivity type impurity at a surface of the semiconductor substrate at a part of the pixel, and divided into an open region and a fixed region having a pinning layer whose top part is doped by the first conductive type impurity; and
a metal oxide semiconductor (MOS) type reset transistor having a source region that is partially overlapped with the photodiode region at the open region and doped by a relatively high-concentration second conductivity type impurity.

2. The CMOS image sensor as claimed in claim 1, wherein the source region is partially overlapped with a gate electrode of the reset transistor, and
the open region of the photodiode region reaches to a sidewall of the gate electrode.

3. The CMOS image sensor as claimed in claim 1, wherein the source region reaches to a sidewall of a gate electrode of the reset transistor, and
the open region of the photodiode region is spaced from the sidewall of the gate electrode by a certain distance.

4. The CMOS image sensor as claimed in claim 3, wherein the certain distance is half of the width of the source region.

5. The CMOS image sensor as claimed in claim 1, wherein the channel region of the reset transistor is doped by the same type of impurity as the photodiode region but by a concentration relatively lower than the photodiode region, so that the potential of the channel region is relatively lower than that of the photodiode region and higher than zero potential, in a state in which no voltage is applied at the gate electrode of the reset transistor.

6. The CMOS image sensor as claimed in claim 1, wherein the drain region of the reset transistor is doped with the same degree of concentration as the source region, and a constant voltage VDD is applied thereon.

7. The CMOS image sensor as claimed in claim 1, wherein the pixel further comprises:
a read out transistor comprising a gate electrode electrically connected with the source region of the reset transistor and a drain region connected with a constant voltage VDD; and
a row selection transistor comprising a drain region connected with the source region of the read out transistor, a gate electrode connected with a gate line formed at the entire region of sensing the image, and a source region connected with a constant current circuit and a output terminal.

8. The CMOS image sensor as claimed in claim 1, wherein the first conductivity type impurity is P-type impurity, and the second conductivity type impurity is an N-type impurity.

9. The CMOS image sensor as claimed in claim 1, wherein the entire surface of the substrate is covered by a gate insulation layer.

10. The CMOS image sensor as claimed in claim 1, wherein the channel of the reset transistor is formed of at least one of a buried channel and a surface channel.
